(19) United States
(12) Patent Application Publication
(10) Pub. No.: US 2024/0139765 A1
(43) Pub. Date: May 2, 2024

(54) APPARATUS FOR DISPENSING DROPLET AND MEASURING METHOD FOR FLOATING AMOUNT OF SUBSTRATE THEREOF

(71) Applicant: SEMES CO., LTD., Chungcheongnam-do (KR)

(72) Inventor: Ji Hun KANG, Chungcheongnam-do (KR)

(21) Appl. No.: 18/126,358

(22) Filed: Mar. 24, 2023

(30) Foreign Application Priority Data
Nov. 1, 2022 (KR) 10-2022-0143371

(51) Int. Cl. B05B 12/12; B05B 13/04

(52) U.S. Cl. CPC B05B 12/124; B05B 13/0447

(57) ABSTRACT

The present disclosure is to provide an apparatus for dispensing droplets. Provided is an apparatus for dispensing droplets, the apparatus including: a stage on which a substrate is disposed and spraying holes are disposed; a substrate moving unit for moving the substrate disposed on the stage in a first direction; a droplet dispensing unit disposed in a vertical direction above the substrate; and a droplet dispensing unit moving unit moving the droplet dispensing unit in a second direction, perpendicular to the first direction on a horizontal plane, the apparatus, further including: a distance measuring unit measuring a distance from a substrate in the vertical direction; and a control unit, wherein the control unit measures a distance between the distance measuring unit and the substrate through the distance measuring unit while moving the substrate through the substrate moving unit.

### CROSS-REFERENCE TO RELATED APPLICATION(S)

This application claims the benefit under 35 USC 119(a) of Korean Patent Application No. 10-2022-0143371 filed on Nov. 1, 2022 in the Korean Intellectual Property Office, the entire disclosure of which is incorporated herein by reference for all purposes.

### BACKGROUND

The present disclosure relates to an apparatus for dispensing droplets while a substrate is floated and a measuring method for a floating amount of a substrate thereof.

For display devices such as organic EL display devices, a manufacturing process, such as a process for dispensing droplets, or the like, is being performed while targeting a substrate having a larger area with each generation.

In the process for dispensing droplets, targeting on a large-area substrate, there are cases in which the substrate is moved using a floating stage of floating the substrate by ejected air.

In the case of the floating stage, a floating amount is determined by ejected air, and when the floating amount is not constant, droplets may not be dispensed accurately. Accordingly, an operator measures the floating amount through a distance measuring device, and based thereon, the droplets are dispensed.

However, the floating may change depending on a position at which the floating amount is measured in the floating stage, and since the position at which the floating amount is measured is different for each operator, a reliability problem occurs in the measured data.
(Patent Document 1) KR 10-2022-0021726 A

### SUMMARY

An aspect of the present disclosure is to provide an apparatus for dispensing droplets capable of measuring a floating amount or a measuring method for a floating amount of a substrate of the apparatus for dispensing droplets.

In an embodiment, an aspect of the present disclosure is to provide an apparatus for dispensing droplets capable of providing information on clogging of a spraying hole for floating a substrate and a method for measuring a floating amount thereof.

In order to achieve the above object, an aspect of present disclosure is to provide an apparatus for dispensing droplets and a method for measuring a floating amount of the apparatus for dispensing droplets as follows.

According to an aspect of the present disclosure, provided is an apparatus for dispensing droplets, the apparatus including: a stage on which a substrate is disposed and spraying holes through which gas is sprayed from a lower portion of the substrate to the substrate; a substrate moving unit moving the substrate disposed on the stage in a first direction along the stage; a droplet dispensing unit disposed in a vertical direction above the substrate; and a droplet dispensing unit moving unit connected to the droplet dispensing unit, and moving the droplet dispensing unit in a second direction, perpendicular to the first direction on a horizontal plane, the apparatus for dispensing droplets further including: a distance measuring unit connected to the droplet dispensing unit, and measuring a distance from a substrate in the vertical direction; and a control unit connected to the substrate moving unit, the droplet dispensing unit moving unit, the droplet dispensing unit, and the distance measuring unit, wherein the control unit measures a distance between the distance measuring unit and the substrate through the distance measuring unit while moving the substrate through the substrate moving unit.

According to an aspect of the present disclosure, provided is a method for measuring a floating amount of a substrate of an apparatus for dispensing droplets including a stage on which a substrate is disposed and spraying holes through which gas is sprayed from a lower portion of the substrate to the substrate are disposed; a substrate moving unit for moving the substrate disposed on the stage; a droplet dispensing unit disposed in a vertical direction above the substrate; and a droplet dispensing unit moving unit connected to the droplet dispensing unit, and moving the droplet dispensing unit, the method including: a floating amount measuring operation for measuring a floating amount of a substrate by measuring a distance thereof from the substrate in the vertical direction through a distance measuring unit connected to the droplet dispensing unit while changing a position of the distance measuring unit with respect to the substrate.

According to an aspect of the present disclosure, provided is a method for measuring a floating amount of a substrate of an apparatus for dispensing droplets including a stage on which a substrate is disposed and spraying holes through which gas is sprayed from a lower portion of the substrate to the substrate are disposed; a substrate moving unit for moving the substrate disposed on the stage; a droplet dispensing unit disposed in a vertical direction above the substrate; and a droplet dispensing unit moving unit connected to the droplet dispensing unit, and moving the droplet dispensing unit, the method including: a state checking operation of a distance measuring unit for checking a state of the distance measuring unit at intervals of a predetermined number of substrates; a floating amount measuring operation for measuring a floating amount of a substrate by measuring a distance from the substrate in the vertical direction through the distance measuring unit while changing a position of the distance measuring unit with respect to the substrate, wherein the floating amount measuring operation includes a moving and measuring operation in a first direction for moving a position of the distance measuring unit in a first direction, in which the stage is formed to be extended from the substrate through the substrate moving unit or the droplet dispensing unit moving unit, and a moving operation in a second direction for moving a position of the distance measuring unit in a first direction, perpendicular to the first direction from the substrate, through the substrate moving unit or the droplet dispensing unit moving unit, wherein the moving and measuring operation in the first direction and the moving operation in the second direction are alternately performed.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic diagram illustrating a conventional measurement method.

FIGS. 2A and 2B are a schematic diagram illustrating measurement according to the measurement position of FIG. 1.

FIG. 3 is a side schematic side view of an apparatus for dispensing droplets according to an embodiment of the present disclosure.

FIG. 4 is a plan schematic view of an apparatus for dispensing droplets according to an embodiment of the present disclosure.

FIGS. 5A and 5B are a schematic diagram illustrating a relationship between measuring a floating amount of a distance measuring unit and clogging of spraying holes.

FIG. 6 is a flowchart of a method for measuring a floating amount of an apparatus for dispensing droplets according to an embodiment of the present disclosure.

FIG. 7 is a detailed flow chart of an operation for measuring a floating amount in the method for measuring a floating amount of FIG. 6.

FIG. 8 is a schematic plan view of the apparatus for dispensing droplets in the operation for measuring a floating amount of FIG. 7.

FIG. 9 is a detailed flowchart of an operation of checking a state of the distance measuring unit in FIG. 6.

FIG. 10 is a plan schematic view of an apparatus for dispensing droplets in the operation of checking a state of the distance measuring unit of FIG. 9.

FIG. 11 is a graph illustrating a measured value measured in the operation of measuring a floating amount thereof of an embodiment of the present disclosure.

FIG. 12 is a flow chart of a method for measuring a floating amount of an apparatus for dispensing droplets according to another embodiment of the present disclosure.

### DETAILED DESCRIPTION

Hereinafter, preferred embodiments of the present disclosure will be described in detail so that those skilled in the art could easily practice the present disclosure with reference to the accompanying drawings. However, in describing a preferred embodiment of the present disclosure in detail, if it is determined that a detailed description of a related known function or configuration may unnecessarily obscure the subject matter of the present disclosure, the detailed description will be omitted. In addition, the same reference numerals are used throughout the drawings for parts having similar functions and actions. In addition, in the present specification, terms such as ‘upper,’ ‘upper portion,’ ‘upper surface,’ ‘lower,’ ‘lower portion,’ ‘lower surface,’ ‘side surface,’ and the like are based on the drawings, and in practice, it may be different depending on a direction in which the components are disposed.

In addition, throughout the specification, when a part is said to be ‘connected’ to another part, this is not only when it is ‘directly connected,’ but also when it is ‘indirectly connected’ with other components therebetween. In addition, ‘including’ a certain component means that other components may be further included without excluding other components unless otherwise stated.

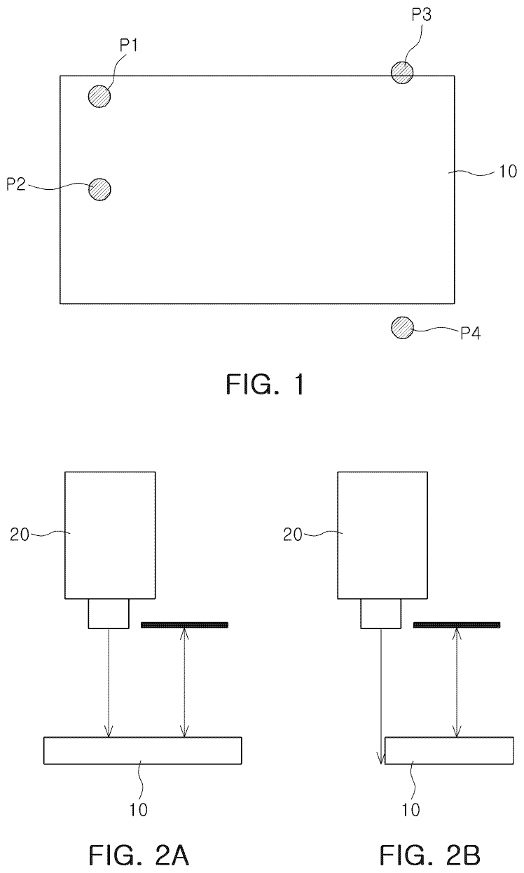

FIG. 1 is a schematic diagram illustrating a conventional measurement method, and FIG. 2A and FIG. 2B are a schematic diagram illustrating a state of measurement according to the measurement position of FIG. 1.

In the present disclosure, the apparatus for dispensing droplets 1 (see FIG. 4) is for dispensing droplets to a substrate 10 when a display device such as an organic EL device is manufactured, and is for dispensing droplets to each of a plurality of pixels formed on the substrate 10.

The substrate 10 may be moved in a state floated by a stage 50 (see FIG. 4), of the apparatus for dispensing droplets 1, the stage 50 may have a plurality of spraying holes formed therein to float the substrate 10, and gas is sprayed from the spraying holes, so that the substrate 10 floats on the stage 50.

The spraying hole may be clogged due to an inflow of droplets or an inflow of foreign substances, and when the spraying hole is clogged and the floating is not performed smoothly, a floating position of the substrate 10 is changed and a distance between a droplet discharge head and the head 10 is changed, so that the droplets may not accurately be dispensed.

Meanwhile, the apparatus for dispensing droplets 1 is set again after a certain time interval or work, and as shown in FIG. 1, an operator measures a distance from the substrate 10 through a distance measuring unit 20 connected to a droplet dispensing unit 100 (see FIG. 4) at arbitrary positions P1 to P4, and the distance measuring unit 20 is set based on the measured distance and checks a state of the device. However, as shown in FIGS. 1 and 2, a measured position is not constant depending on the operator, and different floating amounts can be measured in the same device 1 depending on the measured position, so it is difficult to check an accurate state of the device, and the setting is changed and data obtained therefrom is changed, so that reliability of data obtained through the distance measuring unit 20 may not be secured.

Furthermore, when communication between the distance measuring unit 20 and the control unit is unstable, a measured value may not be obtained, or a measured value may be inaccurate due to communication.

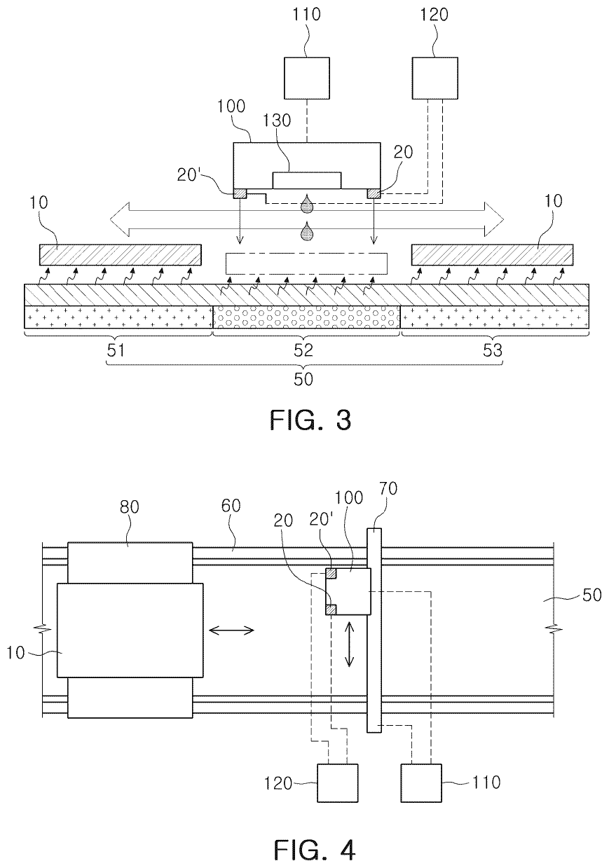

The present invention solves the above problems, and FIGS. 3 and 4 illustrate a schematic side view and a plan view of an apparatus for dispensing droplets 1 according to an embodiment of the present disclosure.

As shown in FIGS. 3 and 4, the apparatus for dispensing droplets 1 includes a stage 50, substrate moving units 60 and 80 for moving the substrate on the stage 50 in a first direction, droplet dispensing unit 100 disposed above the stage 50, and a droplet dispensing unit moving unit 70 connected to the droplet dispensing unit 100, and including a gantry extending in a second direction, perpendicular to the first direction.

The stage 50 accommodates and supports the substrate 10 so that the substrate 10 is disposed when the droplets are dispensed, and may be provided to have a size capable of accommodating a large-area substrate suitably in a recent process for dispensing droplets, requiring a large-area, and may be provided to have a size that does not interfere with a transfer of a large-area substrate.

The stage 50 is configured so that a plurality of spraying holes (not shown) are disposed toward the substate 10 to float the substrate 10. The stage 50 includes spraying regions 51 and 53 for spraying gas toward a bottom surface of the substrate 10, that is, a surface opposite to the surface facing the droplet dispensing unit 100, and a spraying and vacuum region 52 for simultaneously providing gas spraying and gas suction. A region for transferring the substrate 10 on the stage 50 is composed of spraying regions 51 and 53, and a region for dispensing droplets to the substrate 10, that is, below the droplet dispensing unit 100, is composed of a spraying and vacuum region 52.

The stage 50 in the transfer section of the substrate 10 may be provided to spray only gas toward a back surface of the substrate 10, since a height at which the substrate 10 floats may be appropriately adjusted, and the stage 50 in the discharge section of droplets, may be configured to provide spraying and vacuum to the back surface of the substrate 10 together, since a height at which the substrate 10 floats should be precisely adjusted.

The substrate moving units 60 and 80 include a holding unit 80 for holding the substrate 10 on at least one side thereof, a guide member 60 for guiding the holding unit 80 to move in a first direction along the stage 50, and a driving unit for providing driving force to the holding unit 80. The holding unit 80 may be formed to have a configuration of holding each of one end portion of the substrate and the other end portion of the substate 10 by vacuum suction of the back surface of the substrate 10, or directly holding each of one end portion of the substrate and the other end portion of the substrate 10.

The droplet dispensing unit 100 is provided to dispense droplets to the substrate 10 disposed on the stage 50, and is configured to be movable in a second direction, perpendicular to the first direction in which the substrate 10 is transferred from the upper portion of the stage 50 on a horizontal plane.

The droplet dispensing unit 100 includes a discharge head 130 provided to discharge droplets to the substrate 10 in a jetting manner. The droplet dispensing unit 100 may be connected to the droplet dispensing unit moving unit 70 including a gantry and may be moved in the second direction, and the discharge head 130 of the droplet dispensing unit 100 may have one or more distance measuring units 20 and 20′, and when the droplet dispensing unit 100 is moved in the second direction by the droplet dispensing unit moving unit 70, the distance measuring units 20 and 20′ may also be moved together.

The distance measuring units 20 and 20′ are devices for measuring a distance between the distance measuring units 20 and 20′ and the substrate 10 in a non-contact manner, and may be laser measuring devices, but are not limited thereto. In this embodiment, there are two distance measuring units 20 and 20′, and the distance between the substrate 10 and the distance measurement unit 20 is measured through one of the distance measuring units 20.

The apparatus for dispensing droplets 1 includes a device control unit 110 and a distance measuring unit control unit 120. The device control unit 110 is connected to the stage 50, the substrate moving units 60 and 80, the droplet dispensing unit moving unit 70, and the droplet dispensing unit 100 to perform overall control of the apparatus for dispensing droplets 1, and the distance measuring unit control unit 120 is connected to the distance measuring units 20 and 20′ to perform control related to manipulation of the distance measuring units 20 and 20′ and processing measured data. The device control unit 110 and the distance measuring unit control unit 120 are connected to each other in a wired or wireless manner. In this embodiment, the device control unit 110 and the distance measuring unit control unit 120 are described as being respectively provided, but the present disclosure is not limited thereto, and the overall control of the device and the control of distance measuring units 20 and 20′ may also be simultaneously performed through one control unit.

The apparatus for dispensing droplets 1 according to an embodiment of the present disclosure floats a floating amount of an entire region of the substrate 10, through the device control unit 110 and the distance measuring unit control unit 120. That is, when the substrate 10 enters, by changing a position of the distance measuring units 20 and 20′ with respect to the substrate 10 through the substrate moving units 60 and 80 and the droplet dispensing unit moving unit 70 in a certain manner, information on the floating amount of the entire region of the substrate 10 is obtained. In the case of the distance measuring unit 20, a distance between the substrate 10 and the distance measuring unit 20 is measured, and a distance between the distance measuring unit 20 and the stage 50 is a fixed value, and by subtracting the measured value and a thickness of the substrate, from the distance between the distance measuring unit 20 and the stage 50, the floating amount may be obtained.

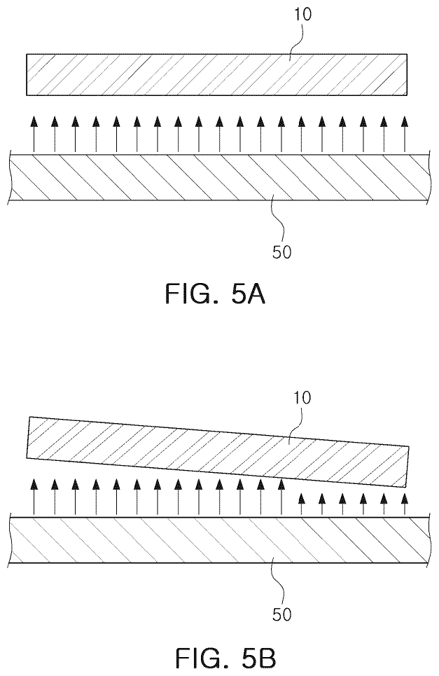

As shown in FIG. 5A and FIG. 5B, a spraying hole is blocked, sufficient spraying is not performed to the corresponding portion, so the substrate 10 is lowered to other portions, and the distance between the substrate 10 and the distance measuring unit 20 is increased. That is, when the spraying hole is clogged, the floating amount appears to be small.

Since a plurality of spraying holes are disposed on the stage 50, even if one or two spraying holes are clogged, it may not immediately lead to a change in the floating amount, but the floating amount of the substrate 10 may be changed according to a position of the substrate 10 on the spraying holes of the stage 50. For example, when some spraying holes are clogged on the stage 50, there are many spraying holes floating together when passing through a central portion of the substrate 10, so the floating amount may not be changed, and in the case of being toward an edge of the substrate 10, as the number of spraying holes decreases so the floating amount may be changed, and this change in the floating amount may not occur only at one point, and may occur at a plurality of points according to the position at which the substrate 10 is moved.

Since the substrate moving units 60 and 80 move the substrate 10 in a first direction, and the droplet dispensing unit moving unit 70 moves the substrate 10 in a second direction, by alternately the substrate movement through 60 and 80 and the substrate movement through the droplet dispensing unit moving unit 70, by measuring the floating amount for the entire region of the substrate 10, the device control unit 110 may provide information on whether or not the spraying hole is clogged.

For example, by moving the substrate 10 through the substrate moving units 60 and 80 by a length of the substrate 10 in a first direction in a forward direction substrate moving direction to measure a floating amount and then moving the same by a predetermined distance in a second direction, through the droplet dispensing unit moving unit 70, then moving the substrate 10 by a length of the substrate 10 in a first direction in a backward direction through the substrate moving units 60 and 80, and then moving the same by a predetermined distance in a second direction, information on the floating amount in the entire region of the substrate 10, that is, the distance between the distance measuring unit 20 and the substrate 10 may be obtained.

In particular, in the case of measuring the distance from the distance measuring unit 20 after being moved by a certain interval, information on the floating amount for the position of the substrate 10 may be obtained, and the position in which the spraying holes are clogged may be specified, so that not only operation efficiency may be improved, but also overall productivity of the device may also be improved by reducing maintenance time.

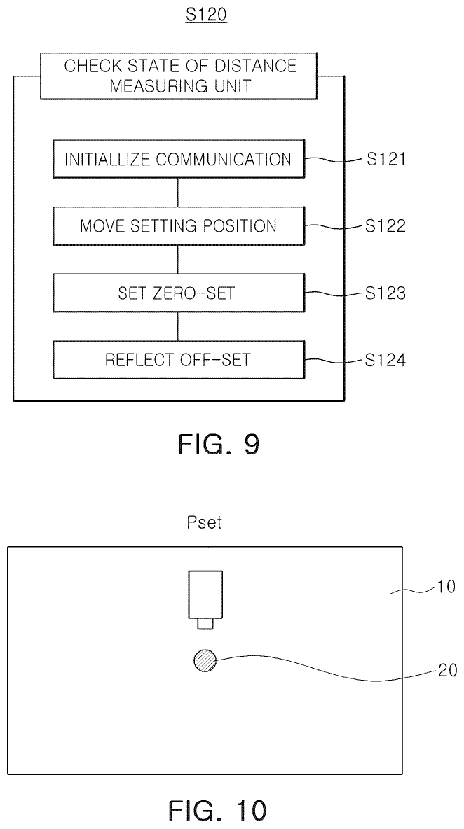

In addition, the device control unit 110 checks a state of the distance measuring unit 20 before measuring the floating amount on the substrate 10 in order to collect reliable data for measuring the floating amount performed at regular intervals. In order to check communication between the distance measuring unit control unit and the distance measuring unit control unit 120, a state of the distance measuring unit 20 may be performed by re-connecting the communication, and moving the distance measuring unit 20 to a predetermined position Pset (see FIG. 9), so that settings of the distance measuring unit 20 are maintained each time, and then measuring a distance between the substrate 10 and the distance measuring unit 20 to obtain a floating amount. Then, the settings of the distance measuring unit 20 may be initialized based on the floating amount.

The measurement of the floating amount is performed by measuring the distance between the distance measuring units 20 and 20′ and the substrate 10 through the distance measuring units 20 and 20′ while changing a position of the substrate 10 or the droplet discharge unit 100 between the substrates 10, so that the floating amount is obtained in the corresponding position. Information on the clogging of the spraying holes on the stage 50 corresponding to the corresponding position of the substrate 10 may be checked through information on the floating amount according to each position, and by measuring the floating amount at regular intervals while printing on the substrate 10 is performed, it is possible to accurately check the state of the device 1.

In addition, after a predetermined number of substrates 10 are normally printed, a floating amount for an entire region or partial regions of a next incoming substrate 10 may be measured, and the measured result may be compared with before/after, so that not only the state of the device may not only be accurately identified, but also it is possible to predict in advance an erroneous discharge of the droplets by identifying a portion where the floating amount is reduced.

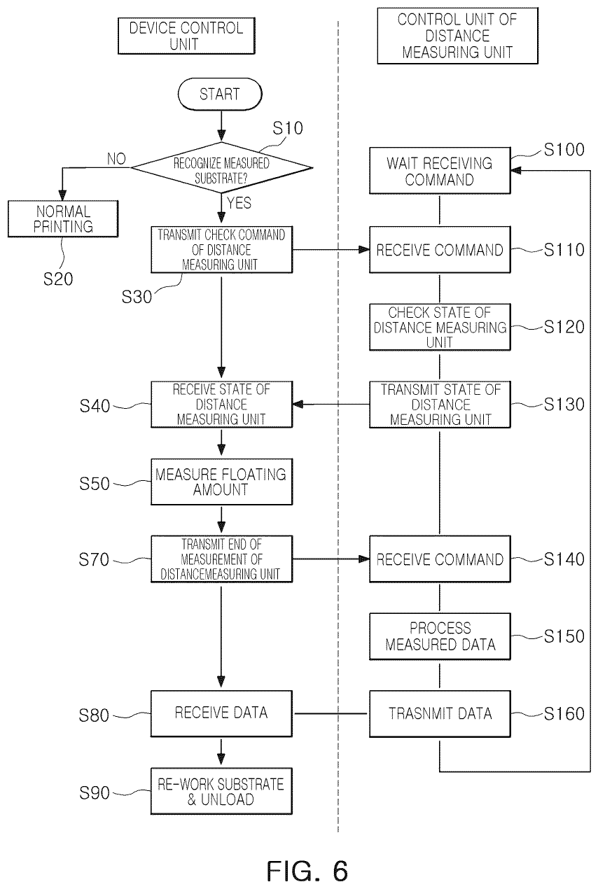

A method for measuring a floating amount of the device control unit 110 and the distance measuring unit control unit 120 as described above will be described again with reference to FIGS. 6 to 10.

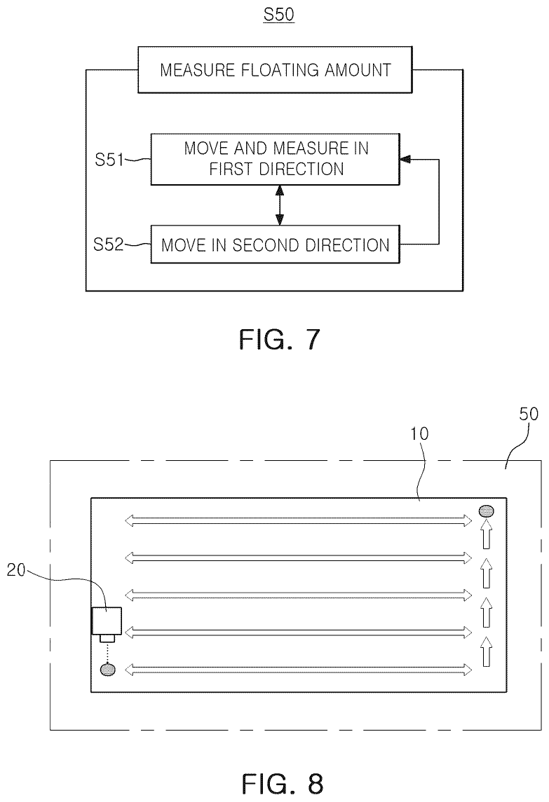

FIG. 6 illustrates a flow chart of a method for measuring a floating amount of an apparatus for dispensing droplets according to an embodiment of the present disclosure, FIG. 7 illustrates a detailed flow chart of an operation of measuring a floating amount in the method for measuring a floating amount of FIG. 6, FIG. 8 illustrates a schematic plan view of the apparatus for dispensing droplets in the operation for measuring a floating amount of FIG. 7, FIG. 9 illustrates a detailed flowchart of an operation of checking a state of the distance measuring unit of FIG. 6, and FIG. 10 illustrates a schematic plan view of the apparatus for dispensing droplets in the operation of checking a state of the distance measuring unit of FIG. 9.

The floating amount measuring method of FIG. 6 is described based on the apparatus for dispensing droplets 1 illustrated in FIGS. 3 and 4, and includes a device control unit 110 and a distance measuring unit control unit 120, so that a sequence thereof is performed in each of the control units 110 and 120 is illustrated.

When a substrate 10 enters, the device control unit 110 determines whether the substrate 10 is a target substrate for measuring a floating amount (S10). Measurement of the floating amount is not always performed, and the floating amount is measured at regular intervals of the number of sheets thereof to continuously observe and predict the state of the device. When the substrate 10 does not correspond to the measuring substrate (‘No’ in S10), normal printing is performed (S20), and when it corresponds to the measuring substrate (‘Yes’ in S10), a command to check the distance measuring unit is transmitted to the distance measuring unit control unit 120.

The distance measuring unit control unit 120 is in a command receiving waiting operation (S100), receives the check command (S110), and checks a state of the distance measuring unit 20 (S120). The state checking operation of the distance measuring unit (S120) may include a communication initialization operation (S121), a setting position moving operation (S122), a zero-set setting operation (S123), and an off-set reflection operation (S124), which will be described with FIGS. 8 and 9 together later.

After checking the state of the distance measuring unit (S120) is performed, the distance measuring unit control unit 120 transmits a result of checking the state of the distance measuring unit to the device control unit 110 (S130), and the device control unit 110 receives the check result (S40) and then performs a floating amount measuring operation (S50) of measuring a floating amount of the substrate 10. As illustrated in FIG. 7, the floating amount measuring operation (S50) may include a moving and measuring operation in a first direction (S51) for measuring a floating amount at regular distance intervals while being moved in a first direction, and a moving operation in a second direction (S52) for moving the same at a certain distance in a second direction.

The floating amount measuring operation (S50) ends after the measurement of the floating amount for an entire region of the substrate or a specific region to be measured is completed, the device control unit 110 transmits an end command of measuring a distance for notifying the end of measurement of the distance measuring unit to the distance measuring unit control unit 120, the distance measuring unit control unit 120 receives the corresponding command (S140), processes the measured floating amount data (S150), and transmits the data to the device control unit 110 (S160). Thereafter, the distance measuring unit control unit 120 returns to the command receiving waiting operation (S100), and the device control unit 110 receives the floating amount measured data (S80), and re-works and unloads the substrate 10 (S90). A data providing operation of providing position information on clogging of spraying holes from a floating amount measured for each position after receiving the floating amount measured data (S80) may be further performed.

The floating amount measurement data may be stored inside the device control unit 110 or in an external storage space connected to the device control unit 110, and by comparing the same with existing floating amount measurement data, a current state of the device may be checked, and may be used as data to track the clogged portion of the spraying holes of the stage 50.

The measured substrate 10 may perform normal printing (S20) without unloading, but a printing time for one sheet of the substrate 10 is measured for a long time due to the measurement of the floating amount, so that accurate information on printing may not be provided, so that it is unloaded without normal printing.

Referring to FIGS. 7 and 8, a floating amount measuring operation will be described in detail. After receiving a state of the distance measuring unit 20 (S40), a floating amount measuring operation (S50) is performed, and the floating amount measuring operation (S50) includes a moving and measuring operation in a first direction (S51) for moving a position of the distance measuring unit 20 from the substrate 10 in a first direction, in which the stage 50 is formed to be extended, through the substrate moving units 60 and 80 or the droplet dispensing unit moving unit 70, and a moving operation in a second direction (S52) for moving a position of the distance measuring unit 20 from the substrate in a second direction, perpendicular to the first direction, through the substrate moving units 60 and 80 or the droplet dispensing unit moving unit 70. In the moving operation thereof in the second direction (S52), it is not necessary to measure a floating amount through the distance measuring unit, but it is okay to measure the floating amount, similarly to the moving and measuring operation thereof in the first direction (S51). In the floating amount measuring operation (S50), the moving and measuring operation thereof in the first direction (S51) and the moving operation thereof in the second direction (S52) may be alternately performed.

In this embodiment, since the substrate moving units 60 and 80 move the substrate 10 in a first direction, in the moving and measuring operation thereof in the first direction (S51), the floating amount is measured through the distance measuring unit 20 while moving the substrate 10 through the substrate moving units 60 and 80 by a predetermined first distance the first direction. In addition, since the droplet dispensing unit moving unit 70 moves the droplet discharge unit 100 in a second direction, in the moving operation thereof in the second direction (S52), the droplet discharge unit 100 is moved by a predetermined second distance through the droplet dispensing unit moving unit 70.

The floating amount measuring operation (S50) is to measure a distance from the substrate 10 through the distance measuring unit 20 while changing a position of the distance measuring unit 20 on the substrate 10, to find out a floating amount. Since setting of the distance measuring unit 20 was performed by checking the state of the distance measuring unit (S120), reliable data can be provided.

The floating amount measuring operation (S50) is performed at one point of the substrate 10, and is performed again after a relative position of the substrate 10 and the distance measuring unit 20 is changed, and this floating amount measurement may be performed over an entire region or performed for partial regions of the substrate 10.

As shown in FIG. 8, the floating amount of the substrate 10 is measured at regular intervals while moving the substrate 10, in a forward direction of the first direction, by a length of the substrate in a first direction or by a length longer than the length of the substrate 10 in the first direction, that is, in a direction in which the substrate 10 passes through the droplet discharge unit 100, and the floating amount of the substrate 10 is measured at regular intervals while moving the substrate 10, in a direction, opposite to the previous first direction movement, by a length of the substrate in the first direction or by a length, longer than the length of the substrate 10 in the first direction, that is, a backward direction of the first direction. Thereafter, by repeating a routine of moving the droplet dispensing unit 100 in the second direction, the distance measuring unit 20 measures the floating amount over an entire region or an entirety of the target regions of the substrate 10.

Alternatively, the floating amount of the substrate 10 may be measured while reciprocating in the first direction, and after moving the droplet discharge unit 100 in the second direction, the floating amount of the substrate may be measured while reciprocating in the first direction again, and then the floating amount of the substrate may also be measured while reciprocating in the second direction again.

In particular, by making a moving interval in the first direction and a moving interval in the second direction constant, respectively, a position of the substrate 10, from which the floating amount measurement data and the corresponding data are obtained may be checked, so that, when the floating amount is small, it is possible to accurately check a position in which the clogging of the spraying hole occurred on the stage 50.

Referring to FIGS. 9 and 10, an operation of checking a state of the distance measuring unit (S120) will be described.

The operation of checking a state of the distance measuring unit (S120) is for securing reliability of data of a floating amount obtained by the distance measuring unit 20, and may include a communication initialization operation (S121) of initializing a communication state from the distance measuring unit 20; a set position moving operation (S122) for moving the distance measuring unit 20 to a first set position Pset of the substrate 10 through the substrate moving units 60 and 80 and the droplet dispensing unit moving unit 70; a zero-set setting operation (S123) for adjusting setting of the distance measuring unit 20 based on a floating amount measured at the first set position Pset; and an off-set reflection operation of reflecting a position setting value of the individual distance measuring unit 20 after the zero-set setting.

In order to check whether communication between the distance measuring unit 20 and the control unit of the distance measuring unit 120 is accurately connected, the communication initialization operation (S121) is an operation of initializing communication regardless of whether or not they have been previously connected. Through the communication initialization operation (S121), since the communication connection is confirmed between the distance measuring unit 20 and the control unit of the distance measuring unit 120, it is possible to prevent the reliability of the data for measuring a floating amount obtained subsequently from being damaged due to a communication problem.

In the setting position moving operation (S122), the substrate 10 is moved to the substrate moving units 60 and 80 in a first direction so that the distance measuring unit 20 measures a floating amount at a predetermined first setting position Pset of the substrate 10, to prevent an operator from setting the distance measuring unit 20 at individually manipulated positions and so that setting is performed in the same position consistently, and the distance measuring unit 20 is moved to the droplet dispensing unit moving unit 70 in a second direction. As described above, as the substrate 10 and the distance measuring unit 20 are moved in the first and second directions, the distance measuring unit 20 is positioned on the first setting position Pset of the substrate 10. The first set position Pset may be a central portion of the substrate 10.

The zero-set setting operation (S123) means an operation of measuring a floating amount of the substrate 10 through the distance measuring unit 20 at the first setting position (Pset) and then setting the floating amount to 0 (zero). Even if there is no zero-set setting, a relative change can be known, but to check an accurate change in the floating amount, the zero-set setting is performed.

After the zero-set setting is completed, a measured value is modified to provide accurate floating amount data by reflecting an off-set reflecting the individual characteristics of the distance measuring unit 20. That is, the zero-set setting operation (S123) and the off-set setting operation (S124) are performed to reflect an off-set value for matching the measured floating amount with an actual floating amount, so that the data measured in the distance measuring unit 20 coincides with the actual floating amount. The off-set value may change according to a position where the distance measuring unit 20 is mounted on the droplet dispensing unit 100.

Through the operation of checking a state of the distance measuring unit (S120), reliability of the data measured by the distance measuring unit 20 can be ensured, and it is confirmed that the data obtained from the substrate 10 that is continuously measured, such as not only the substrate 10 for measuring a floating amount this time, but also the substrate 10 for measuring a floating amount next, are accurately measured data, so that a state of the stage 50 of the apparatus for dispensing droplets 1 may be checked from the floating amount of different substrates 10, so that management of the apparatus for dispensing droplets 1 is facilitated.

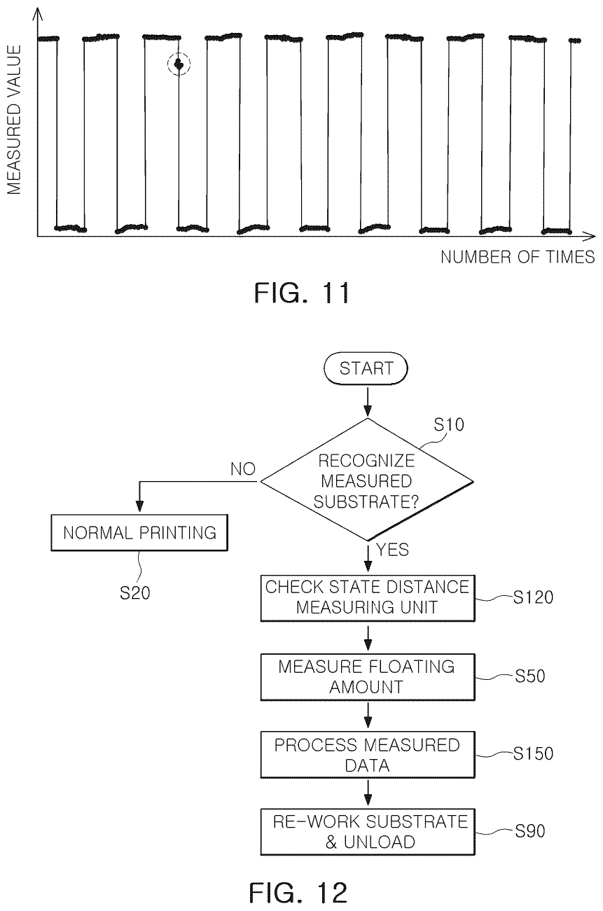

FIG. 11 illustrates data obtained by measuring a floating amount of the substrate 10 in the apparatus for discharging droplets 1 according to an embodiment of the present disclosure.

The data of FIG. 11 is moved as shown in FIG. 8, but the movement thereof in a second direction is performed at a position outside the substrate 10, and has a form in which a first value measured from the substrate 10 and a second value measured at a position outside the substrate 10 are repeated for a certain period. As shown in a circular display portion of FIG. 11, when the spraying hole is clogged, one value is not lowered, but a third value between the first value and the second value is obtained for a certain period toward the clogged section. This data is obtained through the distance measuring unit control unit 120 and the device control unit 110, and when the third value is continuously found, it is determined that a clog has occurred at the corresponding position, and a user may be notified of the position where the clog has occurred. However, it is also possible to store data in a storage unit provided in the device control unit 110 or an external storage unit provided externally without immediate notification, and provide the corresponding information to the user when the user checks.

Since a plurality of spraying holes are disposed on the stage 50, even if one or two spraying holes are clogged, it may not immediately lead to a change in a floating amount, but according to a position of the substrate 10 on the spraying hole of the stage 50, a change in the floating amount of the substrate 10 may occur. In particular, when moved to an edge of the substrate 10, the position of the spraying holes involved in the floating of the substrate 10 is changed, and as the number of the spraying holes involved decreases, a change in the floating amount may occur.

FIG. 12 illustrates another embodiment of a method for measuring a floating amount of the present disclosure.

In the method of measuring a floating amount of FIG. 12, a device control unit 110 and a distance measuring unit control unit 120 are not separately provided, but are controlled together by a single control unit 110.

As in the embodiment of FIG. 6, the device control unit 110 checks whether the corresponding substrate 10 is a target substrate for measuring a floating amount when the substrate 10 is introduced (S10). Measurement of the floating amount is not always performed, and the floating amount is measured at regular intervals of the number of sheets thereof to continuously observe and predict a state of the device. When the corresponding substrate does not correspond to the target substrate for measuring a floating amount (‘No’ in S10), normal printing is performed (S20), and when the corresponding substrate does not correspond to the target substrate for measuring a floating amount (‘Yes’ in S10), a state of the distance measuring unit 20 is checked (S120). As described in FIGS. 8 and 9, the operation for checking a state of the distance measuring unit (S120) may include a communication initialization operation (S121), a set position moving operation (S122), a zero-set setting operation (S123), and an off-set reflection operation (S124).

After checking the state of the distance measuring unit (S120), the apparatus control unit 110 may perform a floating amount measuring operation (S50) for measuring a floating amount of the substrate 10. As illustrated in FIG. 7, in the floating amount measuring operation (S50), a moving and measuring operation thereof in a first direction (S51) and a moving operation thereof in a second direction (S52) are alternately performed.

The floating amount measuring operation (S50) ends after measurement of the floating amount for an entire substrate 10 is completed, the apparatus control unit 110 processes the measured floating amount data (S150) and then reworks the substrate 10 and unloads the same (S90).

The floating amount measured data may be stored inside an apparatus control unit 110 or an external storage space connected to the apparatus control unit 110, and by comparing the floating amount measured data with existing floating amount measured data, a current state of the device may be checked, and it may be used as data to track clogging of spraying holes of the stage 50.

In addition, although not illustrated, a data providing operation of transmitting data of tracking position information on clogging of spraying holes on the stage 50 based on the floating amount measured in the floating amount measuring operation (S50) and position information of the distance measuring unit on the substrate to a user or other control unit may be included, and a notification step of notifying the user based on the data may be included.

Meanwhile, in an embodiment, although it has been described that the apparatus for dispensing droplets 1 moves the substrate 10 in a first direction through the substate moving units 60 and 80, and moves the droplet dispensing unit 100 in a second direction through the droplet dispensing unit moving unit 70, the present disclosure may have a different configuration if the droplet dispensing unit 100 is moved to a predetermined position of the substrate 10. For example, the droplet dispensing unit 100 may move the substrate 10 in first and second directions in a fixed state, and conversely, the droplet dispensing unit 100 may be moved in the first and second directions in a state in which the substrate 10 is fixed.

As set forth above, according to an aspect of the present disclosure, an apparatus for dispensing droplets capable of measuring a floating amount or a method for measuring a floating amount of the apparatus for dispensing droplets may be provided through the above configuration.

In an embodiment of the present disclosure, an apparatus for dispensing droplets capable of providing information on clogging of spraying holes for floating a substrate and a method for measuring a floating amount may be provided.

In the above, the embodiment of the present invention has been mainly described, but the present disclosure is not limited thereto and may be variously modified and implemented.

While exemplary embodiments have been shown and described above, it will be apparent to those skilled in the art that modifications and variations could be made without departing from the scope of the present invention as defined by the appended claims.

What is claimed is:

1. An apparatus for dispensing a droplet, comprising:
a stage on which a substrate is disposed and spraying holes through which gas is sprayed from a lower portion of the substrate to the substrate are disposed;
a substrate moving unit for moving the substrate disposed on the stage in a first direction along the stage;
a droplet dispensing unit disposed in a vertical direction above the substrate; and
a dispensing unit moving unit connected to the droplet dispensing unit, and moving the droplet dispensing unit in a second direction, perpendicular to the first direction on a horizontal plane,
the apparatus, further including:
a distance measuring unit connected to the droplet dispensing unit, and measuring a distance from a substrate in the vertical direction; and a control unit connected to the substrate moving unit, the dispensing unit moving unit, the droplet dispensing unit, and the distance measuring unit,
wherein the control unit measures a distance between the distance measuring unit and the substrate through the distance measuring unit while moving the substrate through the substrate moving unit.

2. The apparatus for dispensing droplets of claim 1,
wherein the control unit measures a distance between the distance measuring unit and the substrate through the distance measuring unit, while alternately performing movement of a substrate for moving the substrate in the first direction through the substrate moving unit and performing movement of a droplet dispensing unit for moving the droplet dispensing unit in the second direction through the droplet dispensing unit moving unit.

3. The apparatus for dispensing droplets of claim 2, wherein the control unit measures a distance between the distance measuring unit and the substrate after checking a state of the distance measuring unit.

4. The apparatus for dispensing droplets of claim of claim 3, wherein, when checking the state of the distance measuring unit, the control unit re-connects communication from the distance measuring unit.

5. The apparatus for dispensing droplets of claim 4, wherein, when checking the state of the distance measuring unit, the control unit moves the distance measuring unit to a first position on a horizontal plane and then measures a distance from the substrate, and initialize setting of the distance measuring unit to a measured value at the first position.

6. The apparatus for dispensing droplets of claim 3, wherein the droplet dispensing unit comprises a discharge head, and
the distance measuring unit is connected to the discharge head.

7. As a method for measuring a floating amount of a substrate of an apparatus for dispensing droplets, the apparatus including a stage on which a substrate is disposed and spraying holes through which gas is sprayed from a lower portion of the substrate to the substrate are disposed; a substrate moving unit for moving the substrate disposed on the stage; a droplet dispensing unit disposed in a vertical direction above the substrate; and a droplet dispensing unit moving unit connected to the droplet dispensing unit, and moving the droplet dispensing unit,
the method comprising:
a floating amount measuring operation for measuring a floating amount of a substrate by measuring a distance from the substrate in the vertical direction through a distance measuring unit connected to the droplet dispensing unit while changing a position of the distance measuring unit with respect to the substrate.

8. The method of claim 7, wherein the floating amount measuring operation comprises
a moving and measuring operation in a first direction for moving a position of the distance measuring unit from the substrate in a first direction, in which the stage is formed to be extended through the substrate moving unit or the droplet dispensing unit moving unit, and a moving operation in a second direction for moving a position of the distance measuring unit from the substrate in a second direction, perpendicular to the first direction, through the substrate moving unit or the droplet dispensing unit moving unit,
wherein the moving and measuring operation in the first direction and the moving operation in the second direction are alternately performed.

9. The method of claim 7, wherein the floating amount measuring operation comprises
a moving and measuring operation in a first direction for moving the substrate in a first direction, in which the stage is formed to be extended through the substrate moving unit, and a moving operation in a second direction for moving the distance measuring unit in a second direction, perpendicular to the first direction, through the droplet dispensing unit moving unit,
wherein the moving and measuring operation in the first direction and the moving operation of in the second direction are alternately performed.

10. The method of claim 9, wherein, in the moving and measuring operation in the first direction, the substrate is moved by a first distance in a first direction and then measured, and
in the moving and measuring operation in the second direction, the distance measuring unit is moved by a second distance.

11. The method of claim 10, wherein, in the moving and measuring operation in the first direction, the movement in the first direction comprises forward movement and backward movement, and in the moving and measuring operation in the first direction after performing the moving operation in the second direction, the forward direction and backward direction in the first direction are converted.

12. The method of claim 10, further comprising:
a state checking operation of a distance measuring unit for checking a state of the distance measuring unit,
wherein the state checking operation of the substrate includes a communication initialization operation for initializing communication between the distance measuring unit and a control unit of the apparatus for dispensing droplets.

13. The method of claim 12, wherein the state checking operation further comprises
a setting position moving operation for moving the distance measuring unit to a first position above the substrate through the substrate moving unit or the droplet dispensing unit moving unit.

14. The method of claim 13, wherein the state checking operation further comprises
a zero-set setting operation for measuring a distance from the substate at the first position through the distance measuring unit and then changing setting based on a measured value; and
an off-set reflection operation for reflecting a basic setting to the distance measuring unit, zero-set in the zero-set setting operation.

15. The method of claim 12, wherein the moving operation, the floating amount measuring operation, and the state checking operation are performed separately from dispensing droplets of the droplet dispensing unit, and
after droplets are dispensed to a predetermined number of substrates, the moving operation, the floating amount measuring operation, and the state checking operation are performed.

16. The method of claim 15, further comprising:
an unloading operation for unloading the substrate on which the floating amount measuring operation has been performed.

17. The method of claim 16, further comprising:
a data providing operation for providing position information on clogging of spraying holes based on the floating amount measured in the floating amount measuring operation and position information of the distance measuring unit from the substrate.

18. As a method for measuring a floating amount of a substrate of an apparatus for dispensing droplets, the apparatus including a stage on which a substrate is disposed and spraying holes through which gas is sprayed from a lower portion of the substrate to the substrate are disposed; a substrate moving unit for moving the substrate disposed on the stage; a droplet dispensing unit disposed in a vertical direction above the substrate; and a droplet dispensing unit moving unit connected to the droplet dispensing unit, and moving the droplet dispensing unit,
the method comprising:
a state checking operation of a distance measuring unit for checking a state of a distance measuring unit connected to the droplet dispensing unit at intervals of a predetermined number of substrates;
a floating amount measuring operation of measuring a floating amount of a substrate by measuring a distance from the substrate in the vertical direction through the distance measuring unit while changing a position of the distance measuring unit with respect to the substrate,
wherein the floating amount measuring operation includes a moving and measuring operation in a first direction for moving the position of the distance measuring unit from the substrate in a first direction, in which the stage is formed to be extended through the substrate moving unit or the droplet dispensing unit moving unit, and a moving operation in a second direction for moving the position of the distance measuring unit from the substrate in a second direction, perpendicular to the first direction, through the substrate moving unit or the droplet dispensing unit moving unit,
wherein the moving and measuring operation in the first direction and the measuring operation in the second direction are alternately performed.

19. The method of claim 18, wherein the state checking operation of the distance measuring unit comprises
a communication initialization operation for initializing communication between the distance measuring unit and a control unit of the apparatus for dispensing droplets;
a setting position moving operation for moving the distance measuring unit to a first position above the substrate through the substrate moving unit or the droplet dispensing unit moving unit;
a zero-set setting operation for measuring a distance from the substrate at the first position through the distance measuring unit and then changing setting based on a measured value; and
an off-set reflection operation for reflecting a basic setting to the distance measuring unit, zero-set in the zero-set setting operation.

20. The method of claim 18, further comprising:
a data providing operation of providing position information on clogging of spraying holes based on the floating amount measured in the floating amount measuring operation and the position information of the distance measuring unit from the substrate in the moving operation.
